(19) United States
(12) Patent Application Publication
(10) Pub. No.: US 2026/0215332 A1
(43) Pub. Date: Jul. 23, 2026

(54) SEMICONDUCTOR DEVICE

(71) Applicant: FUJI ELECTRIC CO., LTD., Kawasaki-shi (JP)

(72) Inventors: Naoyuki KANAI, Matsumoto-city (JP); Daisuke Inoue, Matsumoto-city (JP)

(73) Assignee: FUJI ELECTRIC CO., LTD., Kawasaki-shi (JP)

(21) Appl. No.: 19/569,426

(22) Filed: Mar. 17, 2026

Related U.S. Application Data
(63) Continuation of application No. PCT/JP2025/006338, filed on Feb. 25, 2025.

(30) Foreign Application Priority Data
Mar. 22, 2024 (JP) 2024-046538

(51) Int. Cl. H10W 76/12; H10W 40/20; H10W 70/20; H10W 76/47

(52) U.S. Cl. CPC H10W 76/165; H10W 40/235; H10W 70/20; H10W 76/47

(57) ABSTRACT

Provided is a semiconductor device that can prevent resin leakage during transfer molding and prevent poor appearance. The semiconductor device includes: semiconductor chips; a frame surrounding the semiconductor chips and covering the semiconductor chips from above; control terminals electrically connected to the semiconductor chips and projecting from a top surface side of the frame; and a sealing resin provided inside the frame and sealing the semiconductor chips.

### CROSS-REFERENCE TO RELATED APPLICATION

This application is a Continuation of PCT Application No. PCT/JP2025/006338, filed on Feb. 25, 2025, and claims the priority of Japanese Patent Application No. 2024-046538, filed on Mar. 22, 2024, the content of which are incorporated herein by reference.

### TECHNICAL FIELD

The present disclosure relates to a semiconductor device (a power semiconductor module).

### BACKGROUND ART

JP2023-157585A discloses a semiconductor device including: a first metal plate having electrical conductivity; a first semiconductor chip placed on the first metal plate and electrically connected to the first metal plate; a first terminal electrically connected to the first semiconductor chip; a second terminal electrically connected to the first metal plate; a first resin member in contact with the first terminal to support the first terminal; and a second resin member placed to seal the first semiconductor chip and cover a region on the first metal plate, the second resin member being a resin member different from the first resin member.

JP2023-110389A discloses a semiconductor device in which a terminal arrangement member includes an insulating substrate and a lead terminal, and the insulating substrate provided with a semiconductor element, a plate-shaped member, the lead terminal, and a conductive member is sealed with resin.

JP2023-088055A and JP2023-061445A disclose semiconductor devices each including: an insulating circuit board; a power semiconductor element provided on the insulating circuit board; a case placed to surround the insulating circuit board and the power semiconductor element; and a sealing material placed inside the case to seal the power semiconductor device. The case is provided with a control terminal.

JP2017-199752A discloses a power module including: a first resin layer sealing an insulating substrate on which a semiconductor device is provided; a shielding layer placed to face at least one surface of the first resin layer; and a second resin layer sealing the at least one surface of the first resin layer and the shielding layer. The power module further includes a gate driver substrate placed to face the second resin layer, and a driver circuit for driving the semiconductor device is placed on a surface of the gate driver substrate which surface is opposite to a surface facing the second resin layer.

### SUMMARY OF INVENTION

### Technical Problem

In order to reduce the size and inductance of a power semiconductor module, a structure in which a control terminal is integrated with a frame and projects from the top surface of the frame is considered. The frame integrated with the control terminal is placed around a semiconductor chip, the frame is held by a metal mold, and the semiconductor chip inside the frame is sealed by transfer molding.

The frame integrated with the control terminal has an opening provided in a central portion of the top surface of the frame, so that the inside of the frame is easily observable at the time when the power semiconductor module is assembled.

However, resin may leak to a gap between the frame and the metal mold via the opening of the frame at the time of transfer molding, which causes poor appearance.

In view of the above problem, an object of the present disclosure is to provide a semiconductor device that can prevent poor appearance.

An aspect of the present disclosure inheres in a semiconductor device including: semiconductor chips; a frame surrounding the semiconductor chips and covering the semiconductor chips from above; control terminals electrically connected to the semiconductor chips and projecting from a top surface side of the frame; and a sealing resin provided inside the frame and sealing the semiconductor chips.

In the aspect of the present disclosure, the frame may include: a frame portion surrounding the semiconductor chips and provided integrally with the control terminals; and a cover portion provided inward of the frame portion and covering the semiconductor chip from above.

In the aspect of the present disclosure, the semiconductor device may further include: a conductive plate provided inside the frame and having a top surface side on which the semiconductor chips are provided; an insulating plate provided on a bottom surface side of the conductive plate inside the frame; and a heat dissipation plate provided on a bottom surface side of the insulating plate inside the frame and having a bottom surface exposed from the frame.

In the aspect of the present disclosure, the frame may have a lateral surface on which upper and lower beam portions and support portions connecting the upper and lower beam portions to each other are provided.

In the aspect of the present disclosure, the lateral surface of the frame may have a plurality of openings defined by the upper and lower beam portions and the support portions such that the sealing resin is exposed to the plurality of openings.

In the aspect of the present disclosure, the plurality of openings may have different sizes.

In the aspect of the present disclosure, the plurality of openings may be provided on each of two opposite lateral surfaces of the frame.

In the aspect of the present disclosure, the control terminals may project from respective top surface sides of two opposite sides of the frame.

In the aspect of the present disclosure, the semiconductor device may further include an external terminal electrically connected to the semiconductor chips, wherein the frame further may include a terminal arrangement portion connected to the frame portion and provided integrally with the external terminal.

In the aspect of the present disclosure, the semiconductor device may further include a material-removed portion provided in the terminal arrangement portion to be disposed at a position spaced from the frame portion by 3 mm or more.

In the aspect of the present disclosure, the frame portion may have a connecting portion connected to the terminal arrangement portion with a curvature.

In the aspect of the present disclosure, the frame portion may have a connecting portion connected to the terminal arrangement portion and having a thickness of 3 mm or more.

In the aspect of the present disclosure, the terminal arrangement portion may include a material-removed portion, and an inclined portion provided inside the material-removed portion.

In the aspect of the present disclosure, the frame may have two opposite lateral surfaces each including only an opening such that the sealing resin is exposed to the opening.

It should be noted that the above summary of the invention does not list all the necessary features of the present disclosure. Subcombinations of these feature groups can also be inventions.

### BRIEF DESCRIPTION OF DRAWINGS

FIG. 1 is a perspective view of a semiconductor device according to a first embodiment;

FIG. 2A is a side view of the semiconductor device according to the first embodiment;

FIG. 2B is a sectional view of the semiconductor device according to the first embodiment;

FIG. 3 is a perspective view of the semiconductor device according to the first embodiment;

FIG. 4 is a perspective view of the semiconductor device according to the first embodiment;

FIG. 5 is an equivalent circuit diagram of the semiconductor device according to the first embodiment;

FIG. 6 is a perspective view of components of the semiconductor device according to the first embodiment;

FIG. 7 is a side view of components of the semiconductor device according to the first embodiment;

FIG. 8 is a perspective view of components of the semiconductor device according to the first embodiment;

FIG. 9 is a sectional view of components of the semiconductor device according to the first embodiment and a metal mold;

FIG. 10 is a sectional view of components of the semiconductor device according to the first embodiment and the metal mold;

FIG. 11 is a perspective view of components of a semiconductor device according to a comparative example;

FIG. 12 is a side view of components of the semiconductor device according to the comparative example;

FIG. 13 is a sectional view of components of the semiconductor device according to the comparative example and a metal mold;

FIG. 14 is a plan view of the semiconductor device according to the comparative example;

FIG. 15 is a plan view of components of a semiconductor device according to a second embodiment;

FIG. 16 is a plan view of components of a semiconductor device according to a third embodiment;

FIG. 17 is a sectional view taken along a direction of A-A′ in FIG. 16;

FIG. 18 is a plan view of components of a semiconductor device according to a fourth embodiment; and

FIG. 19 is a perspective view of a semiconductor device according to a fifth embodiment.

### DETAILED DESCRIPTION

Hereinafter, first to fifth embodiments of the present disclosure are described with reference to the drawings.

In the following descriptions of the drawings, the same or similar components are denoted by the same or similar reference numerals. It should be understood that the drawings are schematic illustrations, and the relations between thicknesses and planar dimensions, or proportions of thicknesses of layers illustrated below are not drawn to scale. The specific thicknesses or dimensions of the components thus should be referred to as appropriate in accordance with the corresponding explanations as made below. It should also be understood that the relations or proportions of the dimensions between the respective drawings can differ from each other.

In the following descriptions, the directional definitions such as “top”, “bottom”, “upper-lower”, “left”, “right”, and “right-left” are made simply for illustration purposes, and are not intended to limit the technical ideas of the present disclosure. For example, when a direction of a target is turned by 90 degrees and is observed, the term “upper-lower” should be changed to the term “right-left”, and when the direction of the target is turned by 180 degrees, the term “upper-lower” should be reversed.

In addition, the terms “top surface” and “bottom surface” in the following descriptions may be changed to the terms “front surface” and “rear surface”. Further, the terms “first main surface” and “second main surface” used for the components described below refer to main surfaces opposed to each other. For example, when the “first main surface” is defined as a top surface, the “second main surface” is then defined as a bottom surface. Further, the “first main surface” and the “second main surface” as used herein can also be referred to “one of main surfaces” and “the other main surface” respectively.

### First Embodiment

### Structure of Semiconductor Device

As a semiconductor device (a power semiconductor module) according to a first embodiment, the following describes a power semiconductor module constituting a circuit corresponding to one phase (i.e., a three-level circuit) of a three-level power conversion device (a three-level inverter) circuit.

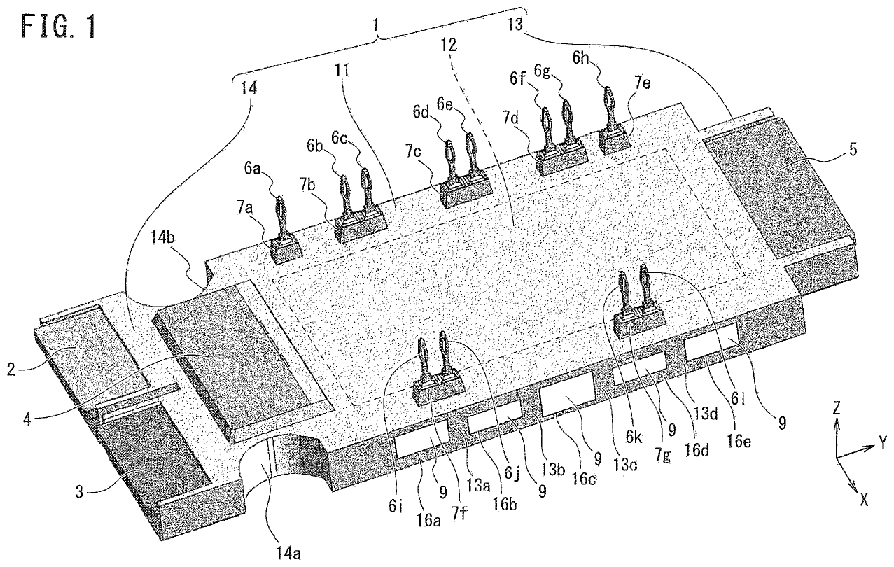

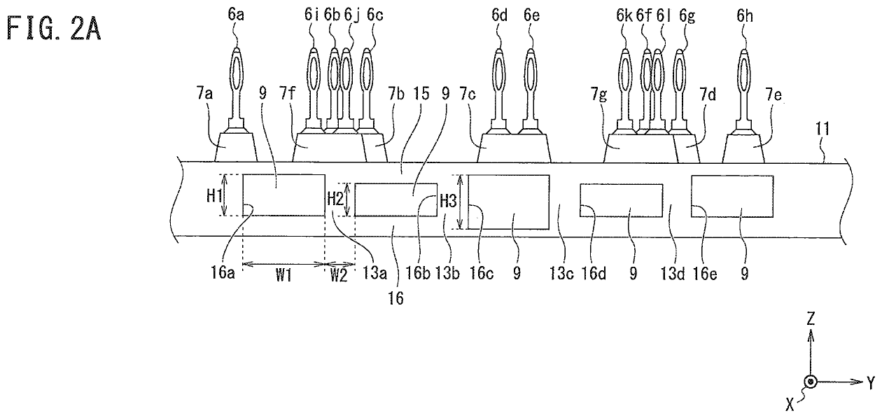

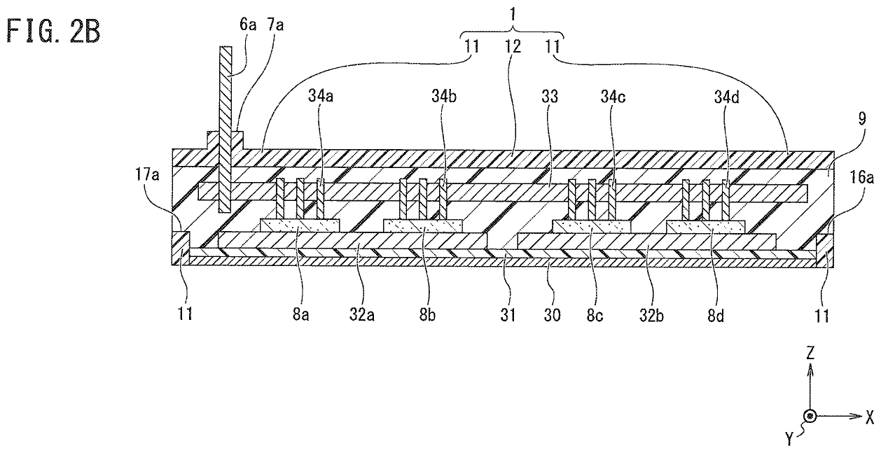

FIG. 1 is a perspective view of the semiconductor device according to the first embodiment. The semiconductor device according to the first embodiment has a generally rectangular solid shape. The short direction of the top surface of the semiconductor device according to the first embodiment is defined as an X-axis direction, and a side (the near side in FIG. 1) provided with control terminals 6i to 6l is defined as an X-axis forward direction. A direction perpendicular to the X-axis direction and also along the longitudinal direction of the top surface of the semiconductor device according to the first embodiment is defined as a Y-axis direction, and a side (the right side in FIG. 1) provided with an output terminal 5 is defined as a Y-axis forward direction. A direction perpendicular to the X-axis direction and the Y-axis direction is defined as a Z-axis direction, and a direction (the upper side in FIG. 1) where the control terminals 6a to 6l extend is defined as a Z-axis forward direction. The definitions of directions in FIG. 2A and its subsequent drawings are also the same as those in FIG. 1.

As illustrated in FIG. 1, the semiconductor device according to the first embodiment includes a frame (case) 1, and a positive terminal 2, a negative terminal 3, an intermediate terminal 4, the output terminal 5, and the control terminals 6a to 6l, which are provided integrally with the frame 1. Although not illustrated in FIG. 1, the frame 1 surrounds a semiconductor chip provided inside the frame 1 and covers the semiconductor chip from above. The frame 1 is made of an insulating resin material such as polyphenylene sulfite (PPS), polybutylene terephthalate (PBT), polyamide (PA), phenol resin, or epoxy-based resin, for example.

The positive terminal 2, the negative terminal 3, the intermediate terminal 4, the output terminal 5, and the control terminals 6a to 6l are external terminals (external connection terminals) connectable to external members. The positive terminal 2, the negative terminal 3, the intermediate terminal 4, the output terminal 5, and the control terminals 6a to 6l are electrically connected to the semiconductor chip provided inside the frame 1. The positive terminal 2, the negative terminal 3, the intermediate terminal 4, the output terminal 5, and the control terminals 6a to 6l are made of a conductive material such as copper (Cu), Cu alloy, aluminum (Al), or Al alloy, for example.

The positive terminal 2, the negative terminal 3, and the intermediate terminal 4 are provided on one end side, in the longitudinal direction, of the semiconductor device according to the first embodiment. The output terminal 5 is provided on the other end side, in the longitudinal direction, of the semiconductor device according to the first embodiment. The positive terminal 2, the negative terminal 3, the intermediate terminal 4, and the output terminal 5 have a flat plate shape, for example. Note that the positive terminal 2, the negative terminal 3, the intermediate terminal 4, and the output terminal 5 may be provided separately, instead of being provided integrally with the frame 1.

FIG. 1 illustrates a case where the control terminals 6a to 6l are each constituted by a press fit pin, but the shapes of the control terminals 6a to 6l are not limited in particular. The control terminals 6a to 6l are provided to project from the top surface side of the frame 1. Since the control terminals 6a to 6l are integrated with the frame 1 and project from the top surface side of the frame 1, it is possible to reduce the size and inductance of the semiconductor device.

The frame 1 includes a frame portion 11, a cover portion 12 provided inward of the frame portion 11, and terminal arrangement portions 13, 14 provided to sandwich the frame portion 11. The frame portion 11 surrounds the semiconductor chip provided inside the frame 1. In a plan view, the frame portion 11 has a generally rectangular shape with a longitudinal direction along the Y-axis direction and a short direction along the X-axis direction. The control terminals 6a to 6l project from respective top surface sides of two opposite sides of the frame portion 11 along the longitudinal direction. The control terminals 6a to 6h are provided on one side out of the two opposite sides of the frame portion 11 along the longitudinal direction, and the control terminals 6i to 6l are provided on the other side out of the two opposite sides of the frame portion 11 along the longitudinal direction.

Protrusions 7a to 7g integrated with the frame portion 11 are provided on the top surface side of the frame portion 11. The control terminal 6a is fixed to the protrusion 7a. The control terminals 6b, 6c are fixed to the protrusion 7b. The control terminals 6d, 6e are fixed to the protrusion 7c. The control terminals 6f, 6g are fixed to the protrusion 7d. The control terminal 6h is fixed to the protrusion 7e. The control terminals 6i, 6j are fixed to the protrusion 7f. The control terminals 6k, 6l are fixed to the protrusion 7g.

The cover portion 12 is provided to cover, from above, the semiconductor chip provided inside the frame portion 11. The terminal arrangement portion 13 is provided integrally with the output terminal 5. The terminal arrangement portion 14 is provided integrally with the positive terminal 2, the negative terminal 3, and the intermediate terminal 4. The terminal arrangement portion 14 has recesses 14a, 14b via which a cover (not illustrated) to be attached to the top surface side of the semiconductor device according to the first embodiment, and a cooling plate (not illustrated) to be attached to the bottom surface side of the semiconductor device according to the first embodiment are fastened by bolts (not illustrated) or the like.

FIG. 2A is a side view of part of the semiconductor device according to the first embodiment illustrated in FIG. 1 when viewed from the X-axis forward direction toward an X-axis negative direction. As illustrated in FIG. 2A, upper and lower beam portions 15, 16 are provided on a lateral surface of the frame portion 11, and support portions 13a to 13d connecting the upper and lower beam portions 15, 16 to each other are provided. Due to the upper and lower beam portions 15, 16 and the support portions 13a to 13d of the frame portion 11, a plurality of openings 16a to 16e is defined on the lateral surface of the frame portion 11. A sealing resin 9 provided inside the frame portion 11 is exposed to the plurality of openings 16a to 16e.

The number of support portions 13a to 13d and the number of openings 16a to 16e are not particularly limited. The openings 16a to 16e may have the same size or may have different sizes. In FIG. 2A, the openings 16a, 16e have a length (height) H1 in the up-down direction, and the length (height) H1 is larger than a length (height) H2 of the openings 16b, 16d in the up-down direction. The length (height) H1 of the openings 16a, 16e in the up-down direction is smaller than a length (height) H3 of the opening 16c in the up-down direction. The openings 16a to 16e may have generally the same width W1 or may have different widths W1. The support portions 13a to 13d may have generally the same width W2 or may have different widths W2.

For example, the openings 16a, 16c, 16e having relatively large sizes may be provided at positions connected with a path through which resin flows in at the time of transfer molding. The openings 16b, 16d having relatively small sizes may be provided at positions not connected with the path through which resin flows in at the time of transfer molding. That is, the resin can easily flow in by increasing the sizes of the openings 16a, 16c, 16e at the positions connected with the path through which resin flows in at the time of transfer molding.

FIG. 2B is a sectional view perpendicular to the Y-axis direction, at a position passing through the control terminal 6a and the opening 16a of the semiconductor device according to the first embodiment illustrated in FIG. 1. An insulating plate 31 is provided inside the frame 1. The insulating plate 31 is made of a material obtained, for example, by mixing a resin material such as liquid crystalline polymer (LCP) or epoxy resin with aluminum oxide (Al₂O₃), aluminum nitride (AlN), silicon nitride (Si₃N₄), boron nitride (BN), or the like as a thermal conductive filler. The insulating plate 31 may be made of a ceramic material such as aluminum oxide (Al₂O₃), aluminum nitride (AlN), or silicon nitride (Si₃N₄), for example.

A heat dissipation plate 30 is provided on a bottom surface side of the insulating plate 31 inside the frame 1. The heat dissipation plate 30 is made of a conductive material such as copper (Cu), Cu alloy, aluminum (Al), or Al alloy, for example. The lateral surface of the heat dissipation plate 30 may be flush with the lateral surface of the insulating plate 31. The bottom surface of the heat dissipation plate 30 is exposed from the frame 1.

Conductive plates 32a, 32b are provided on the top surface side of the insulating plate 31. The conductive plates 32a, 32b are made of a conductive material such as copper (Cu), Cu alloy, aluminum (Al), or Al alloy, for example. The insulating plate 31, the heat dissipation plate 30, and the conductive plates 32a, 32b may be each constituted by an insulating circuit board such as a direct copper bonding (DCB) substrate or an active metal brazing (AMD) substrate.

Semiconductor chips 8a, 8b are provided on the top surface side of the conductive plate 32a via a bonding material (not illustrated) such as solder or a sintered material. Semiconductor chips 8c, 8d are provided on the top surface side of the conductive plate 32b via a bonding material (not illustrated) such as solder or a sintered material.

A semiconductor substrate of each of the semiconductor chips 8a to 8d is made of silicon (Si), silicon carbide (SiC), gallium nitride (GaN), gallium oxide (Ga₂O₃), diamond (C), or the like, for example. The arrangement positions of the semiconductor chips 8a to 8d and the number of semiconductor chips 8a to 8d are not limited particularly. Each of the semiconductor chips 8a to 8d may be a field effect transistor (FET) such as a metal oxide semiconductor field effect transistor (MOSFET), an insulated gate bipolar transistor (IGBT), a reverse conducting insulated gate bipolar transistor (RC-IGBT) in which a diode is connected in anti-parallel with an IGBT, a static induction (SI) thyristor, a gate turn-off (GTO) thyristor, or the like.

A wiring board (printed circuit board) 33 is provided above the semiconductor chips 8a to 8d. The wiring board 33 may be a multilayer wiring board having a plurality of conductive layers. Conductive members 34a to 34d such as pins are fitted by pressing in the wiring board 33. The semiconductor chips 8a to 8d are bonded to the conductive members 34a to 34d via a bonding material (not illustrated) such as solder or a sintered material. The semiconductor chips 8a to 8d are electrically connected to the wiring board 33 via the conductive members 34a to 34d. Note that the semiconductor chips 8a to 8d and the wiring board 33 may be bonded to each other via a bonding materials such as solder or a sintered material or may be bonded to each other via a metal block or the like made of copper or the like, instead of pins.

The control terminal 6a is fitted by pressing in the wiring board 33. The control terminal 6a is electrically connected to the semiconductor chips 8a to 8d via the wiring board 33. The other control terminals 6b to 6l illustrated in FIG. 1 are also fitted by pressing in the wiring board 33. Note that the control terminals 6a to 6l may be fixed to the conductive plates 32a, 32b on the top surface side of the insulating plate 31 or other conductive plates via sleeves or the like.

The sealing resin 9 for sealing the semiconductor chips 8a to 8d is filled inside the frame 1. The sealing resin 9 is made of an insulating resin material such as epoxy-based resin or the like, for example. The sealing resin 9 may be made of the same material as the frame 1 or may be made of a material different from the frame 1. The resin of the frame 1 may have a higher melting point than the molding temperature of the sealing resin 9.

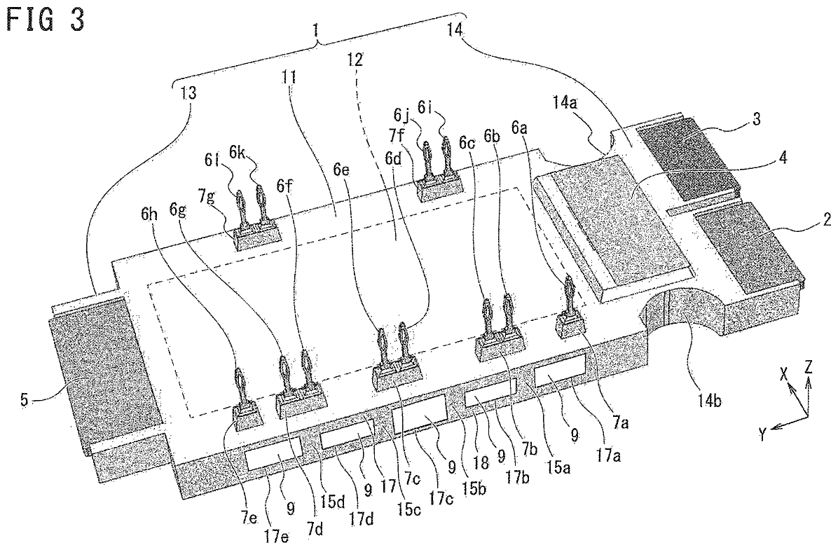

FIG. 3 is a perspective view of the top surface side of the semiconductor device according to the first embodiment when the semiconductor device according to the first embodiment illustrated in FIG. 1 is rotated by 180° around the Z-axis. As illustrated in FIG. 3, upper and lower beam portions 17, 18, and support portions 15a to 15d connecting the upper and lower beam portions 17, 18 to each other are provided on a lateral surface of the frame portion 11 which lateral surface is opposite to the lateral surface provided with the openings 16a to 16e. Due to the upper and lower beam portions 17, 18 and the support portions 15a to 15d, a plurality of openings 17a to 17e is defined. The plurality of openings 17a to 17e is provided at positions opposite to the plurality of openings 16a to 16e. The plurality of openings 17a to 17e has generally the same sizes as the plurality of openings 16a to 16e.

Note that the number of support portions 15a to 15d and the number of openings 17a to 17e may be different from the number of support portions 13a to 13d and the number of openings 16a to 16e, respectively. The positions of the plurality of openings 17a to 17e may not correspond to the positions of the plurality of openings 16a to 16e and may deviate therefrom. The plurality of openings 17a to 17e may have different sizes from the plurality of openings 16a to 16e.

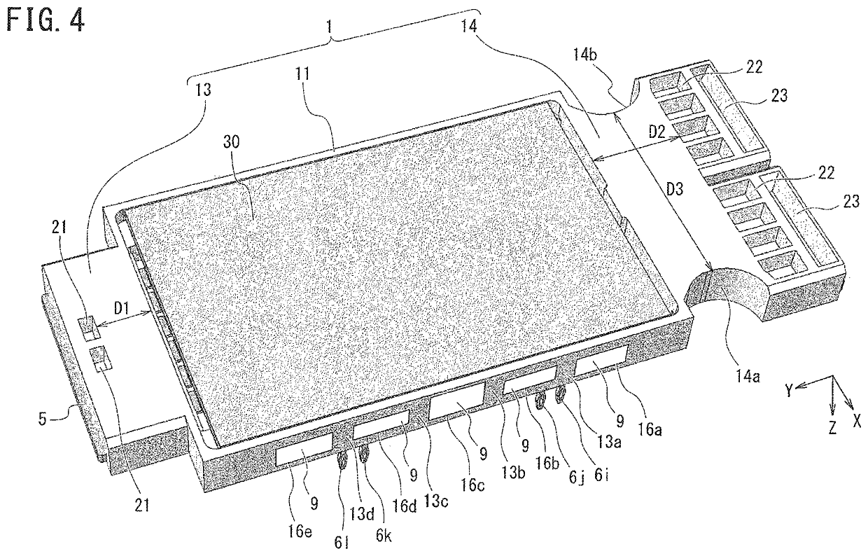

FIG. 4 is a perspective view of the bottom surface side of the semiconductor device according to the first embodiment when the semiconductor device according to the first embodiment illustrated in FIG. 3 is rotated by 180° around the Y-axis. As illustrated in FIG. 4, the bottom surface of the heat dissipation plate 30 is exposed inside the frame portion 11 of the frame 1.

A plurality of material-removed portions (recesses) 21 is arranged in the X-axis direction on the terminal arrangement portion 13 on the output terminal 5 side of the frame 1. A plurality of material-removed portions 22 is arranged in the X-axis direction on the terminal arrangement portion 14 on a side of the frame 1 on which side the positive terminal 2, the negative terminal 3, and the intermediate terminal 4 are provided. The plurality of material-removed portions 22 is provided outward from a portion corresponding to a shortest distance D 3 between the recesses 14a, 14b. A plurality of material-removed portions 23 is provided further outward from the material-removed portions 22 of the terminal arrangement portion 14 to be arranged along the X-axis direction. The material-removed portions 21 to 23 have a function to prevent warpage of the semiconductor device according to the first embodiment.

A distance D1 from the frame portion 11 to the material-removed portions 21 and a distance D2 from the frame portion 11 to the material-removed portions 22 may be, for example, approximately 3 mm or more, approximately 5 mm or more, or approximately 10 mm or more. As the distances D1, D2 are increased to be approximately 3 mm or more, the strength of a region between the frame portion 11 and each of the material-removed portions 21, 22 improves, thereby making it possible to prevent breakage during transfer molding. When the distances D1, D2 are approximately 20 mm or less, for example, it is possible to effectively prevent warpage of the frame 1.

### Circuit Configuration of Semiconductor Device

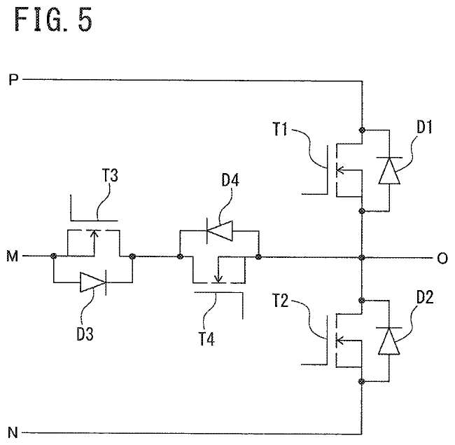

FIG. 5 illustrates an example of an equivalent circuit of the semiconductor device according to the first embodiment. As illustrated in FIG. 5, the semiconductor device according to the first embodiment has a configuration of a three-level circuit and includes a positive terminal P, a negative terminal N, an intermediate terminal M, and an output terminal O.

A drain of a transistor T1 is connected to the positive terminal P. The output terminal O and a drain of a transistor T2 are connected to a source of the transistor T1. The negative terminal N is connected to a source of the transistor T2. A source of a transistor T3 is connected to the intermediate terminal M. A drain of a transistor T4 is connected to a drain of the transistor T3. The output terminal O, the source of the transistor T1, and the drain of the transistor T2 are connected to a source of the transistor T4. Body diodes D1 to D4 serving as a freewheeling diode (FWD) are connected in anti-parallel with the transistors T1 to T4 and incorporated therein.

The positive terminal P, the negative terminal N, the intermediate terminal M, and the output terminal O illustrated in FIG. 5 correspond to the positive terminal 2, the negative terminal 3, the intermediate terminal 4, and the output terminal 5 illustrated in FIG. 1. The transistors T1 to T4 and the body diodes D1 to D4 illustrated in FIG. 5 correspond to semiconductor chips such as the semiconductor chips 8a to 8d illustrated in FIG. 1. Gate terminals of the transistors T1 to T4, auxiliary source terminals, or the like illustrated in FIG. 5 correspond to the control terminals 6a to 6l illustrated in FIG. 1.

### Semiconductor Device Manufacturing Method

Next will be described an example of a manufacturing method (an assembling method) for manufacturing the semiconductor device according to the first embodiment.

First, by a molding method (primary molding) such as transfer molding or injection molding using a metal mold, the frame 1 integrated with the positive terminal 2, the negative terminal 3, the intermediate terminal 4, the output terminal 5, and the control terminals 6a to 6l is formed (see FIG. 1). The wiring board 33 in which the conductive members 34a to 34d are fitted by pressing is prepared (see FIG. 2B). Then, the control terminals 6a to 6l integrated with the frame 1 are fitted by pressing in the wiring board 33 to be integrated therewith.

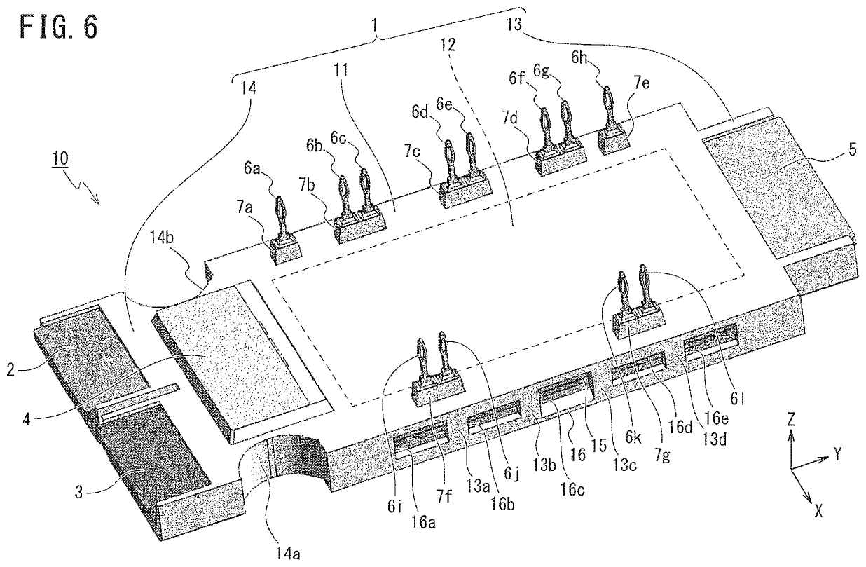

In the meantime, the insulating plate 31 including the conductive plates 32a, 32b provided on the top surface side and the heat dissipation plate 30 provided on the bottom surface side is prepared (see FIG. 2B). The semiconductor chips 8a to 8d are put on the top surface sides of the conductive plates 32a, 32b via bonding materials. The frame 1 and the wiring board 33, which are integrated with each other, are placed to face the top surface sides of the semiconductor chips 8a to 8d. The conductive members 34a to 34d fitted by pressing in the wiring board 33 are put on the top surface sides of the semiconductor chip 8a to 8d via bonding materials. After that, heating or the like is performed to bond the conductive plates 32a, 32b, the semiconductor chips 8a to 8d, the conductive members 34a to 34d, and the like to each other. As a result, a workpiece 10 before transfer molding (secondary molding), as illustrated in FIG. 6 to FIG. 8, is manufactured.

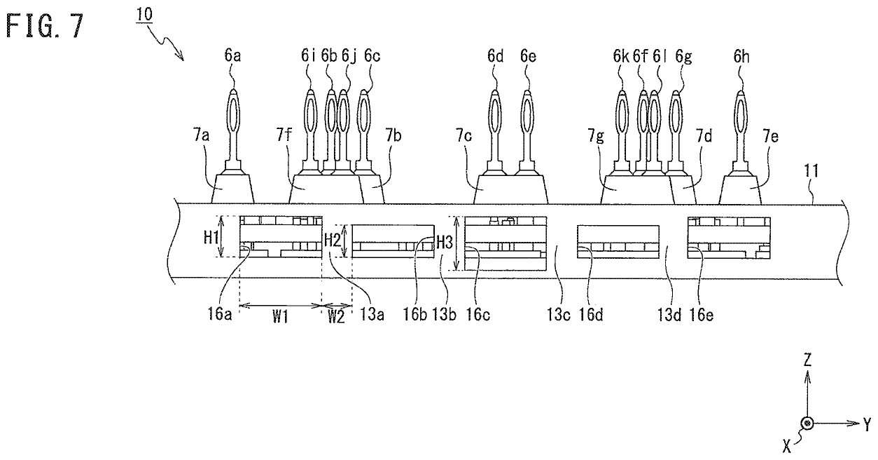

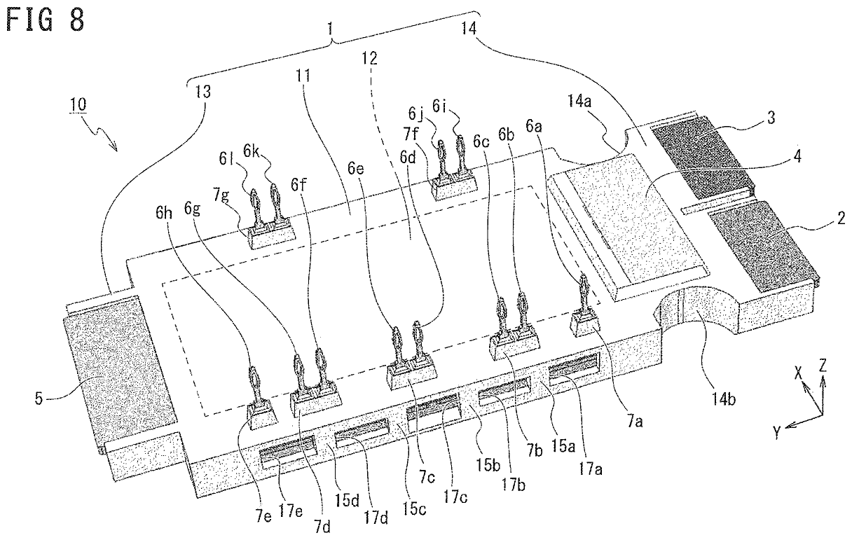

FIG. 6 is a perspective view of the top surface side of the workpiece 10, and FIG. 7 is a side view of part of the workpiece 10. As illustrated in FIG. 6 and FIG. 7, the workpiece 10 is not subjected to transfer molding yet, and therefore, has a structure in which the sealing resin 9 is not filled inside the frame 1 of the semiconductor device according to the first embodiment as illustrated in FIG. 1 and FIG. 2A. The frame 1 surrounds the semiconductor chips 8a to 8d and covers the semiconductor chips 8a to 8d from above. The sealing resin 9 is not filled in the openings 16a to 16e on the lateral surface of the frame portion 11 of the frame 1 yet, and a space is formed inside the frame 1. FIG. 8 is a perspective view of the top surface side of the workpiece 10, obtained by rotating the workpiece 10 illustrated in FIG. 6 by 180° around the Z-axis. The sealing resin 9 is not filled in the openings 17a to 17e on the lateral surface of the frame portion 11 of the frame 1 yet, and a space is formed inside the frame 1.

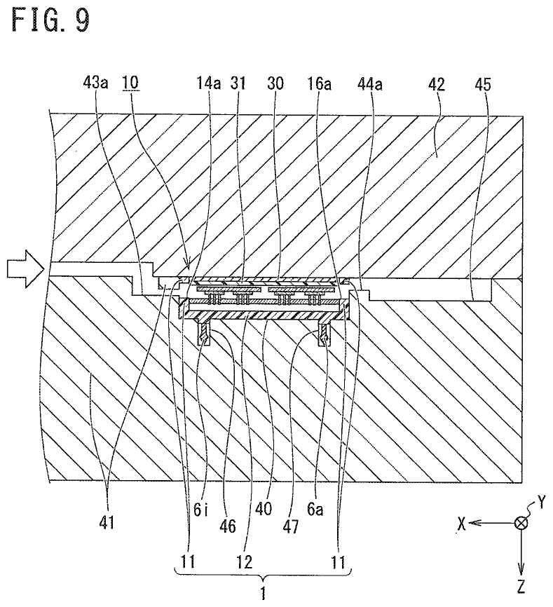

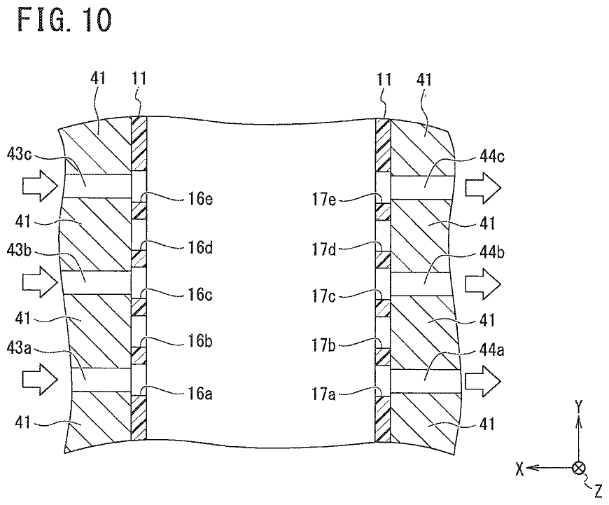

Then, transfer molding is performed such that the sealing resin 9 is filled inside the frame 1 to seal the semiconductor chips 8a to 8d. FIG. 9 is a vertical sectional view illustrating a state where the workpiece 10 is placed in metal molds 41, 42 for transfer molding. FIG. 10 is a horizontal sectional view of the metal mold 41 around the workpiece 10 and illustrates only the frame portion 11 of the workpiece 10.

As illustrated in FIG. 9 and FIG. 10, the metal mold 41 includes a workpiece arrangement portion 40 in which the workpiece 10 is placed, inflow paths (gate runner portions) 43a to 43c through which resin flows in, discharge paths 44a to 44c from which the resin flows out, and a resin accumulation portion 45 in which the resin flowing out is accumulated. The workpiece arrangement portion 40 has recesses 46, 47 in which the control terminals 6a to 6l are placed.

The workpiece 10 is placed in the workpiece arrangement portion 40 of the metal mold 41 to be upside-down such that the top surface side of the frame 1 in the workpiece 10 faces downward, and the bottom surface side of the heat dissipation plate 30 faces upward. The workpiece 10 is placed such that the lateral surface of the frame 1, provided with the openings 16a to 16e, faces the inflow paths 43a to 43c, and the lateral surface of the frame 1, provided with the openings 17a to 17e, faces the discharge paths 44a to 44c. The openings 16a, 16c, 16e are connected to the inflow paths 43a to 43c, and the openings 17a, 17c, 17e are connected to the discharge paths 44a to 44c.

While the workpiece 10 is held by the metal molds 41, 42, resin is introduced in arrow directions in FIG. 9 and FIG. 10 such that the sealing resin 9 is filled inside the frame 1 to seal the semiconductor chips 8a to 8d. Hereby, the semiconductor device according to the first embodiment is completed.

### Comparative Example

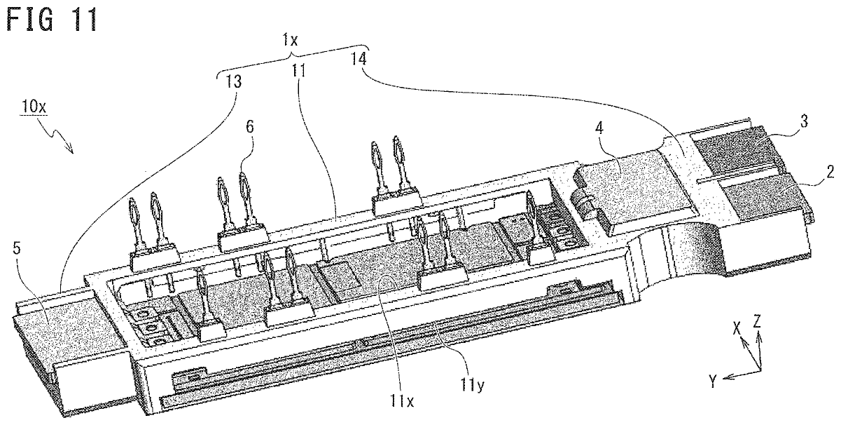

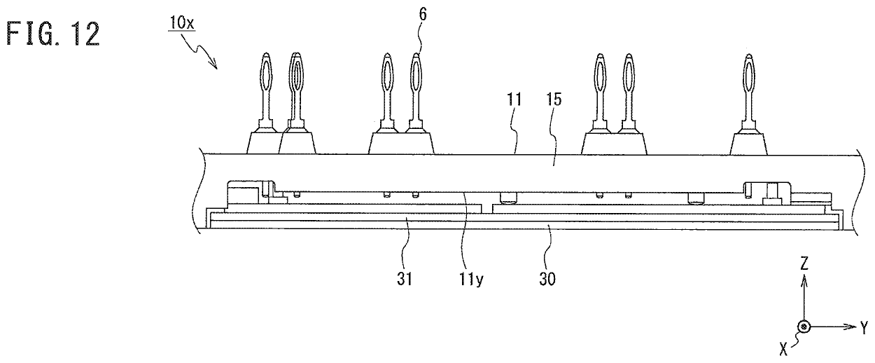

Next will be described a semiconductor device according to a comparative example. FIG. 11 is a perspective view of the top surface side of a workpiece 10x of the semiconductor device according to the comparative example, and FIG. 12 is a side view of part of the workpiece 10x. As illustrated in FIG. 11 and FIG. 12, the workpiece 10x of the semiconductor device according to the comparative example is different from the semiconductor device according to the first embodiment illustrated in FIG. 1 in that no cover portion 12 is provided on the top surface side of a frame 1x integrated with control terminals 6, an opening 11x is formed, so that the inside of the workpiece 10x is easily observable at the time of assembling.

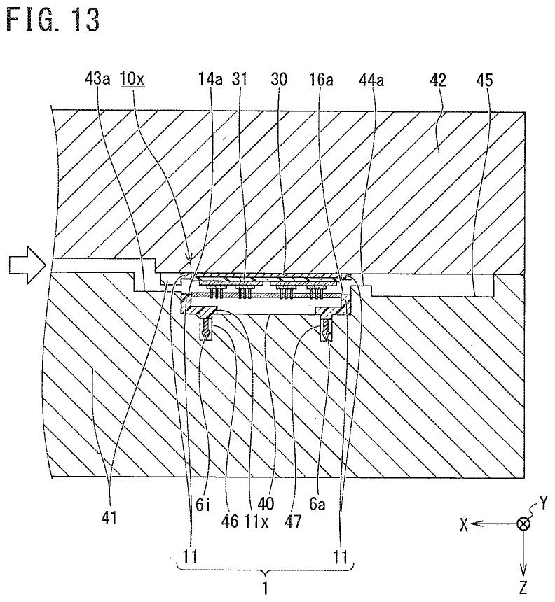

FIG. 13 is a sectional view illustrating the workpiece 10x of the semiconductor device according to the comparative example being placed inside the metal molds 41, 42. As illustrated in FIG. 13, the workpiece 10x is held by the metal molds 41, 42 such that the top surface side of a frame 1x in the workpiece 10x faces downward, and the bottom surface side of the heat dissipation plate 30 faces upward. The top surface of the frame 1x is not necessarily uniformly flat, and a gap is formed between the frame 1x and the metal mold 41 due to warpage or the like of the frame 1x itself. No cover portion 12 is provided on the top surface side of the frame 1x, and the opening 11x is formed. This may cause resin leakage through the opening 11x, which may result in poor appearance. Besides, exposed portions of the control terminals 6a to 6l and the intermediate terminal 4 near the opening 11x may be covered with resin.

In contrast, in the semiconductor device according to the first embodiment, the cover portion 12 is provided for the top surface side of the frame 1, and no opening is formed on the top surface side of the frame 1. As a result, even in a case where the frame 1 is warped, it is possible to prevent resin leakage to the gap between the top surface of the frame 1 and the metal mold 41 at the time of transfer molding as illustrated in FIG. 9, thereby making it possible to prevent poor appearance.

As illustrated in FIG. 11 and FIG. 12, the semiconductor device according to the comparative example is different from the semiconductor device according to the first embodiment in that only the upper beam portion 15 is provided on the lateral surface of the frame portion 11 of the frame 1x, the support portions 13a to 13d and the lower beam portion 16 are not provided, and one opening 11y is provided. In the semiconductor device according to the comparative example, since the support portions 13a to 13d and the lower beam portion 16 are not provided, the frame portion 11 cannot be held by the upper and lower metal molds 41, 42 during transfer molding, which may deform the frame 1x.

In contrast, in the case of the semiconductor device according to the first embodiment, since the support portions 13a to 13d and 15a to 15d are provided on the lateral surfaces of the frame portion 11 of the frame 1, it is possible to hold the frame portion 11 by the upper and lower metal molds 41, 42 during transfer molding, thereby making it possible to prevent deformation of the frame 1.

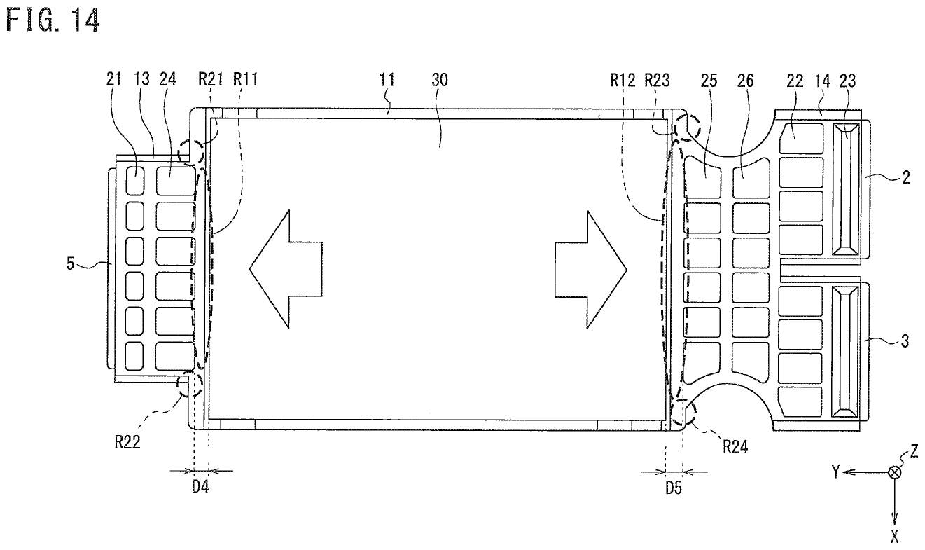

FIG. 14 is a plan view of the bottom surface side of the semiconductor device according to the comparative example. As illustrated in FIG. 14, the semiconductor device according to the comparative example is different from the semiconductor device according to the first embodiment illustrated in FIG. 4 in that material-removed portions 24 are provided in a portion of the terminal arrangement portion 13 of the frame 1x which portion is closer to the frame portion 11 than the material-removed portions 21, and material-removed portions 25, 26 are provided in a portion of the terminal arrangement portion 14 of the frame 1x which portion is closer to the frame portion 11 than the material-removed portions 22. In the semiconductor device according to the comparative example, a region R11 with a distance D4 between the frame portion 11 and the material-removed portions 24 and a region R12 with a distance D5 between the frame portion 11 and the material-removed portions 25 have thin thicknesses and therefore have low strengths. This may cause breakage of the regions R11, R12 between the frame portion 11 and the material-removed portions 24, 25 by pressures caused by resin in the arrow directions during transfer molding, which may cause the resin to enter the material-removed portions 24, 25.

In contrast, in the case of the semiconductor device according to the first embodiment, as illustrated in FIG. 4, no material-removed portions 24 to 26 are provided in regions of the terminal arrangement portions 13, 14 of the frame 1 which regions are close to the frame portion 11, so that the strength of a region between the frame portion 11 and each of the material-removed portions 21, 22 improves. This makes it possible to prevent breakage of the region between the frame portion 11 and each of the material-removed portions 21, 22 during transfer molding.

### Second Embodiment

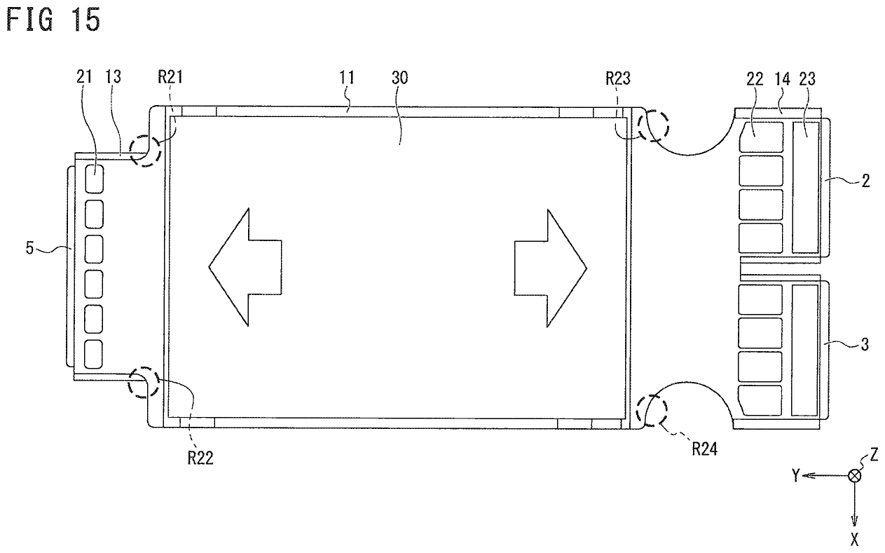

FIG. 15 is a plan view of the bottom surface side of a semiconductor device according to a second embodiment. As illustrated in FIG. 15, the semiconductor device according to the second embodiment is different from the semiconductor device according to the first embodiment in that the frame portion 11 is connected to the terminal arrangement portions 13, 14 with a curvature in regions R21 to R24 where the frame portion 11 of the frame 1 is connected to the terminal arrangement portions 13, 14. The other configuration of the semiconductor device according to the second embodiment is substantially similar to that of the semiconductor device according to the first embodiment, and descriptions thereof are omitted.

In the semiconductor device according to the comparative example illustrated in FIG. 14, a linear portion of the frame portion 11 is connected to a linear portion of each of the terminal arrangement portions 13, 14 in a corresponding region among the regions R21 to R24 where the frame portion 11 of the frame 1x is connected to the terminal arrangement portions 13, 14. In the semiconductor device according to the comparative example illustrated in FIG. 14, the regions R21 to R24 have thin thicknesses, so that the strength of the frame 1x is low. Accordingly, the regions R21 to R24 where the frame portion 11 of the frame 1x is connected to the terminal arrangement portions 13, 14 may be broken by pressures of the resin in the arrow directions during transfer molding, so that the resin flows outside and the external size of the semiconductor device may change.

In contrast, in the case of the semiconductor device according to the second embodiment, a connecting portion of the frame portion 11 of the frame 1 to each of the terminal arrangement portions 13, 14 has a curvature in a corresponding region among the regions R21 to R24 where the frame portion 11 of the frame 1 is connected to the terminal arrangement portions 13, 14, so that the strength of the frame 1 can be improved. This can prevent breakage of the regions R21 to R24 during transfer molding, thereby making it possible to prevent poor appearance.

Note that, instead of the frame portion 11 being connected to the terminal arrangement portions 13, 14 with a curvature, the regions R21 to R24 as connecting portions between the frame portion 11 and the terminal arrangement portions 13, 14 may locally have thick thicknesses. This also makes it possible to improve the strength of the frame 1. The regions R21 to R24 may have a thickness of approximately 3 mm or more, approximately 5 mm or more, or 10 mm or more, for example. As the thicknesses of the regions R21 to R24 are increased to be approximately 3 mm or more, the strength of the frame 1 can be improved, so that breakage of the regions R21 to R24 during transfer molding can be prevented, thereby making it possible to prevent poor appearance.

### Third Embodiment

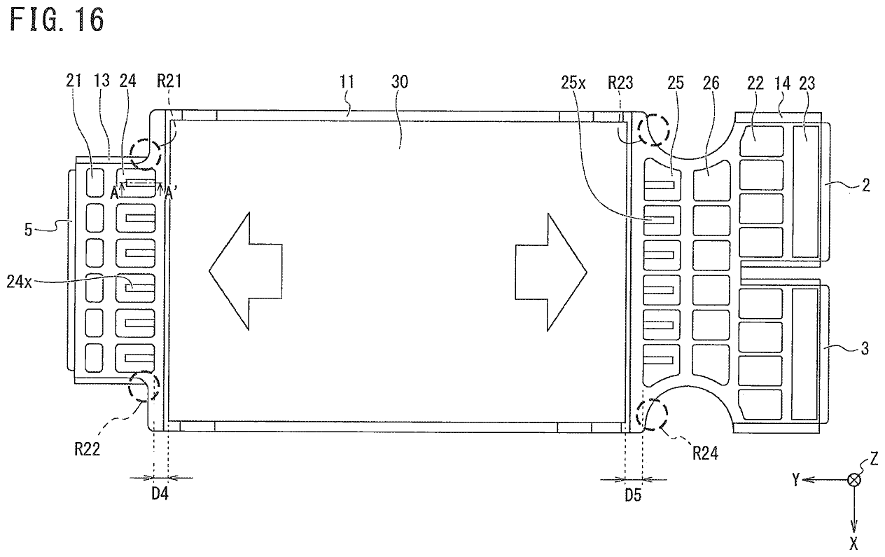

FIG. 16 is a plan view of the bottom surface side of a semiconductor device according to a third embodiment. As illustrated in FIG. 16, the semiconductor device according to the third embodiment is different from the semiconductor device according to the first embodiment in that the material-removed portion 24 in the terminal arrangement portion 13 of the frame 1 includes an inclined portion 24x, and the material-removed portion 25 of the terminal arrangement portion 14 in the frame 1 includes an inclined portion 25x.

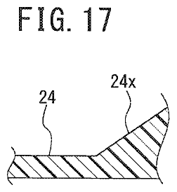

The inclined portion 24x is provided to extend toward the material-removed portion 21 from a central portion of a lateral surface of the material-removed portion 24 which lateral surface is close to the frame portion 11. The distal end of the inclined portion 24x may reach a lateral surface of the material-removed portion 24 which lateral surface is close to the material-removed portion 21. FIG. 17 illustrates a section of the inclined portion 24x in FIG. 16 when viewed from an A-A′ direction. As illustrated in FIG. 17, the inclined portion 24x is inclined such that the height of the inclined portion 24x decreases from the frame portion 11 side toward the material-removed portion 21 side.

The inclined portion 25x illustrated in FIG. 16 is provided to extend toward the material-removed portion 22 from a central portion of a lateral surface of the material-removed portion 25 which lateral surface is close to the frame portion 11. The distal end of the inclined portion 25x may reach a lateral surface of the material-removed portion 25 which lateral surface is close to the material-removed portion 22. Although not illustrated herein, similarly to the inclined portion 24x, the inclined portion 25x is inclined such that the height of the inclined portion 25x decreases from the frame portion 11 side toward the material-removed portion 22 side. The other configuration of the semiconductor device according to the third embodiment is substantially similar to that of the semiconductor device according to the first embodiment, and descriptions thereof are omitted.

In the case of the semiconductor device according to the third embodiment, the material-removed portion 24, 25 of the terminal arrangement portion 13, 14 of the frame 1 includes the inclined portion 24x, 25x. Accordingly, while the material-removed portions 24, 25 prevent warpage of the frame 1, the inclined portions 24x, 25x can secure the strengths of the terminal arrangement portions 13, 14 and prevent resin leakage.

### Fourth Embodiment

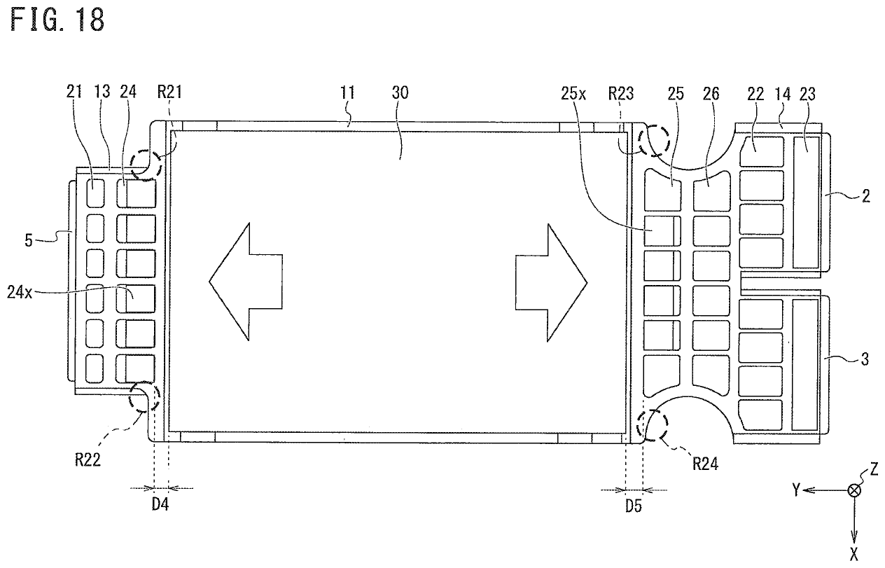

FIG. 18 is a plan view of the bottom surface side of a semiconductor device according to a fourth embodiment. As illustrated in FIG. 18, the semiconductor device according to the fourth embodiment is similar to the semiconductor device according to the third embodiment illustrated in FIG. 16 and FIG. 17 in that the material-removed portion 24, 25 of the terminal arrangement portion 13, 14 of the frame 1 includes the inclined portion 24x, 25x. The semiconductor device according to the fourth embodiment is different from the semiconductor device according to the third embodiment illustrated in FIG. 16 in the shape of the inclined portion 24x, 25x.

The inclined portion 24x is provided to extend toward the material-removed portion 21 from the whole lateral surface of the material-removed portion 24 which lateral surface is close to the frame portion 11 in such a manner as to decrease its height. The inclined portion 25x is provided to extend toward the material-removed portion 22 from the whole lateral surface of the material-removed portion 25 which lateral surface is close to the frame portion 11 in such a manner as to decrease its height. The inclined portion 24x, 25x has a sectional shape similar to the sectional shape of the inclined portion 24x illustrated in FIG. 17. The other configuration of the semiconductor device according to the fourth embodiment is substantially similar to that of the semiconductor device according to the third embodiment, and descriptions thereof are omitted.

In the case of the semiconductor device according to the fourth embodiment, the material-removed portion 24, 25 of the terminal arrangement portion 13, 14 of the frame 1 includes the inclined portion 24x, 25x. Accordingly, while the material-removed portions 24, 25 prevent warpage of the frame 1, the inclined portions 24x, 25x can secure the strengths of the terminal arrangement portions 13, 14 and prevent resin leakage.

### Fifth Embodiment

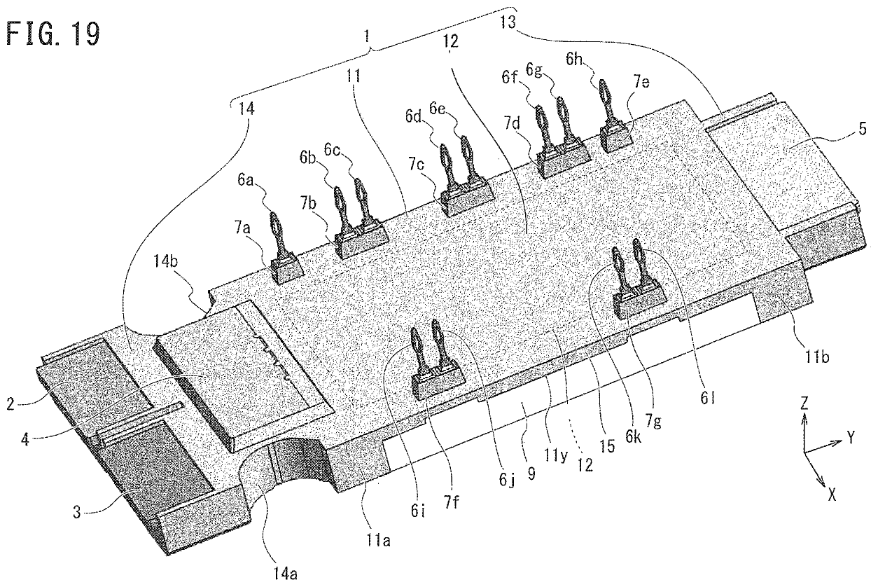

FIG. 19 is a perspective view of the top surface side of a semiconductor device according to a fifth embodiment. As illustrated in FIG. 19, the semiconductor device according to the fifth embodiment is different from the semiconductor device according to the first embodiment illustrated in FIG. 1 in that the support portions 13a to 13d and the lower beam portion 16 are not provided, only the upper beam portion 15 is provided, and one opening 11y is formed on a lateral surface of the frame portion 11 of the frame 1. The sealing resin 9 is exposed to the opening 11y. Although not illustrated herein, similarly to the above, the support portions and the lower beam portion are not provided, only the upper beam portion is provided, and one opening is formed on a lateral surface of the frame portion 11 of the frame 1 which lateral surface is opposite to the lateral surface provided with the opening 11y. The other configuration of the semiconductor device according to the fifth embodiment is substantially similar to that of the semiconductor device according to the third embodiment, and descriptions thereof are omitted.

In the case of the semiconductor device according to the fifth embodiment, the cover portion 12 is provided for the top surface side of the frame 1, so that resin leakage during transfer molding can be prevented, thereby making it possible to prevent poor appearance.

### Other Embodiments

While the present disclosure has been described above according to the first to fifth embodiments, it should be understood that the present disclosure is not intended to be limited to the descriptions and the drawings composing part of the present disclosure. Various alternative embodiments, examples, and technical applications will be apparent to those skilled in the art according to the present disclosure.

For example, each of the first to fifth embodiments describes a case where the semiconductor device includes the positive terminal 2, the negative terminal 3, the intermediate terminal 4, and the output terminal 5 and has a configuration of a three-level circuit. However, the present invention is not limited to this. For example, a semiconductor device may include the positive terminal 2, the negative terminal 3, and the output terminal 5 and have a configuration of a two-level circuit, or may have a configuration of a multi-level circuit of four or more levels.

In addition, the configurations disclosed in the first to fifth embodiments can be combined together as appropriate within a range having no contradiction between the embodiments. It should also be understood that the present disclosure can include various embodiments not disclosed herein. The technical scope of the present disclosure is thus defined only by the subject matter according to the appended claims reasonably derived from the foregoing descriptions.

1. A semiconductor device, comprising:
semiconductor chips;
a frame surrounding the semiconductor chips and covering the semiconductor chips from above;
control terminals electrically connected to the semiconductor chips and projecting from a top surface side of the frame; and
a sealing resin provided inside the frame and sealing the semiconductor chips,
wherein the frame includes a cover portion covering the semiconductor chip from above, and
a bottom surface of the cover portion is in contact with the sealing resin.

2. The semiconductor device according to claim 1, wherein the frame includes:
a frame portion surrounding the semiconductor chips and provided integrally with the control terminals; and
the cover portion provided inward of the frame portion.

3. The semiconductor device according to claim 1, further comprising:
a conductive plate provided inside the frame and having a top surface side on which the semiconductor chips are provided;
an insulating plate provided on a bottom surface side of the conductive plate inside the frame; and
a heat dissipation plate provided on a bottom surface side of the insulating plate inside the frame and having a bottom surface exposed from the frame.

4. The semiconductor device according to claim 1, wherein the frame has a lateral surface on which upper and lower beam portions and support portions connecting the upper and lower beam portions to each other are provided.

5. The semiconductor device according to claim 4, wherein the lateral surface of the frame has a plurality of openings defined by the upper and lower beam portions and the support portions such that the sealing resin is exposed to the plurality of openings.

6. The semiconductor device according to claim 5, wherein the plurality of openings has different sizes.

7. The semiconductor device according to claim 5, wherein the plurality of openings is provided on each of two opposite lateral surfaces of the frame.

8. The semiconductor device according to claim 1, wherein the control terminals project from respective top surface sides of two opposite sides of the frame.

9. The semiconductor device according to claim 2, further comprising an external terminal electrically connected to the semiconductor chips,
wherein the frame further includes a terminal arrangement portion connected to the frame portion and provided integrally with the external terminal.

10. The semiconductor device according to claim 9, further comprising a material-removed portion provided in the terminal arrangement portion to be disposed at a position spaced from the frame portion by 3 mm or more.

11. The semiconductor device according to claim 9, wherein the frame portion has a connecting portion connected to the terminal arrangement portion with a curvature.

12. The semiconductor device according to claim 9, wherein the frame portion has a connecting portion connected to the terminal arrangement portion and having a thickness of 3 mm or more.

13. The semiconductor device according to claim 9, wherein the terminal arrangement portion includes a material-removed portion, and an inclined portion provided inside the material-removed portion.

14. The semiconductor device according to claim 1, wherein the frame has two opposite lateral surfaces each including only an opening such that the sealing resin is exposed to the opening.
